(19) United States
(12) Patent Application Publication
(10) Pub. No.: US 2025/0377314 A1
(43) Pub. Date: Dec. 11, 2025

(54) De-embedding of Electromagnetic Imaging Data on Large Storage Bins

(71) Applicants: GSI Electronique Inc, St-Hubert (CA); University of Manitoba, Winnipeg (CA)

(72) Inventors: Seth James Cathers, Winnipeg (CA); Colin Gerald Gilmore, Winnipeg (CA); Ian Jeffrey, Winnipeg (CA); Joe LoVetri, Winnipeg (CA); Mohammad Asefi, Winnipeg (CA); Kyle Nemez, Winnipeg (CA); Hannah Claire Fogel, Winnipeg (CA); Max Aaron Kelner Hughson, Winnipeg (CA)

(21) Appl. No.: 18/875,639

(22) PCT Filed: May 18, 2023
(86) PCT No.: PCT/IB2023/055131

§ 371 Date: Dec. 16, 2024

Related U.S. Application Data
(60) Provisional application No. 63/367,487, filed on Jun. 30, 2022.

(30) Foreign Application Priority Data
Jul. 15, 2022 (GB) 2210411.1

(51) Int. Cl. G01N 22/04; G01F 23/284; G01R 27/28

(52) U.S. Cl. CPC G01N 22/04; G01F 23/284; G01R 27/28

(57) ABSTRACT

In one embodiment, a system comprising: a container configured to store commodity; a measurement system comprising a vector network analyzer (VNA), a switch module, a plurality of cables, the container, and a plurality of antennas coupled to interior walls of the container, the switch module configured to switch signals transmitted to and received from the plurality of antennas via a plurality of channels, the VNA configured to measure scattering parameters (S-parameters) of all of the plurality of channels; a non-transitory computer readable medium comprising software; and a processor configured by the software to: de-embed a combined effect of the measurement system based on a 2-port network de-embedding technique using only a subset of the S-parameters; and provide an image of the commodity using an inversion algorithm based on input of a calibrated S-parameter after the de-embedding.

### TECHNICAL FIELD

The present disclosure is generally related to electromagnetic imaging of containers, and in particular, calibration of electromagnetic imaging data.

### BACKGROUND

Electromagnetic Imaging (EMI) involves interrogating a target with electromagnetic fields, measuring its response, and using an inversion algorithm to convert these measurements into an image of that target. A recent application of EMI is monitoring grain in storage containers, where multiple antennas transmit and receive electromagnetic signals into the mass of stored grain. The measured fields are then run through an inversion algorithm, which determines the volume, height, cone shape, and relative permittivity of the grain. The relative permittivity of the grain may be used to indicate moisture content of the grain, an important property for safe, long-term storage.

The actual measurements taken from such EMI systems are called Scattering parameters (S-parameters), which are typically measured using a Vector Network Analyzer (VNA). For instance, the VNA transmits energy through a switch and a series of long cables going to each antenna. For microwave networks that have two ports, a network may be fully characterized by taking four S-parameters (S11, S21, S12, and S22). The inversion algorithms, used to generate the images of the grain properties, as described above, usually only use the scattering parameter, S21, measured by the VNA. Industrial use of such systems tend to use low cost electronics, and as such, commercial EMI systems for bin monitoring use a partial VNA that only measures S11 and S21 (but not S12 and S22). These VNAs are available at a reduced cost compared to a full 2-port VNA.

For best imaging results, the true measurements taken at the antenna ports are preferably used. However, this is not possible, since long cables are needed to reach around the large bins, and the signals pass through different channels in an EMI system to reach the measurement device (e.g., the VNA). The channels and cables alter the magnitude and phase of the signal. Further, since each cable length is different, the change to each measurement differs as well. The effects of an EMI measurement system can usually be removed by one of the two following processes, neither of which can directly be used in such systems using a partial VNA: 1) If the full network parameters of the measurement system (e.g., VNA, switch, cables) can be measured, then their effect can be mathematically removed, a process referred to as de-embedding. However, for existing EMI systems using a partial VNA, standard de-embedding methods that depend on knowing the cable parameters are not possible since the cables are cut to size during the installation process and their parameters cannot be measured before being shipped to the customer. It is also not economically practical to perform cable measurements in the field. 2) If all the cables (the connections to the antennas) are systematically attached to a calibration load, the VNA can automatically perform the calibration when each measurement is taken. Again, this is unfeasible to be performed in the field. There are also two additional challenges to the de-embedding process for EMI systems using a partial VNA. For instance, these methods require the full S-parameters, whereas an EMI system using a partial VNA only measures half of the S-parameters for the total system. Also, the parameters fluctuate with temperature, so the process should be able to be performed with each use of the system.

### BRIEF DESCRIPTION OF THE DRAWINGS

Many aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

Some embodiments include a system including a container configured to store a commodity, a measurement system comprising a vector network analyzer (VNA), a switch module, a plurality of cables, and a plurality of antennas coupled to an interior wall of the container, the switch module configured to switch signals transmitted to and received from the plurality of antennas via a plurality of channels, the VNA configured to measure scattering parameters (S-parameters) of all of the plurality of channels, at least processor and at least one non-transitory computer-readable storage medium storing instructions thereon that, when executed by the at least one processor, cause the measurement system to: de-embed a combined effect of the measurement system based on a 2-port network de-embedding technique using only a subset of the S-parameters; and provide an image of the commodity using an inversion algorithm based on input of a calibrated S-parameter after the de-embedding.

The measurement system may de-embed based on a model of the measurement system.

The model of the measurement system may include a series of cascaded 2-port sub-networks for each antenna pair, including a transmission switch channel, a first cable, a device under test (DUT) comprising the container with the plurality of antennas, a second cable, and a receiving switch channel.

The measurement system may measure and store all 2-port S-parameters for all channels, for a range of temperatures, through the switch module when the switch module is not connected to the plurality of cables.

The switch module may include a plurality of amplifiers. The subset of the S-parameters may include S11 and S21 data. The system may also instructions that, when executed by the at least one processor, cause the measurement system: measure the S11 data over a defined frequency band for each antenna with a transmission amplifier among the plurality of amplifiers disengaged; determine an impulse response computed based on the S11 data measurements; determine lengths of the cable based on the impulse response; and model network parameters of the measurement system based further on specifications of the cable and lossy transmission equations.

The measurement system may measure S11 and S21 data for every antenna pair with the transmission amplifier engaged.

The measurement system to may estimate an S22 measurement for the measurement system by: removing the transmission switch channel from the S11 data measurements and approximating S11 data based on the first cable, the DUT, and the second cable; and removing the transmission switch channel from the S22 data measurements and approximating S22 data based on the first cable, the DUT, and the second cable.

The measurement system may determine S12 of the measurement system based on all of the 2-port S-parameters of the channels through the switching module, the cables, and the S11, S21, and S22 measurements.

The measurement system may convert the S-parameters to transmission parameters and perform a standard calibration.

The measurement system may convert bin measurements to S-parameters to obtain calibrated S21 data for use in the inversion algorithm.

The 2-port network de-embedding technique may use ABCD matrices.

Some embodiments include a method for de-embedding a measurement system and imaging commodity in a container, the measurement system comprising a vector network analyzer (VNA), a switch module, plurality of cables, the container, and a plurality of antennas coupled to interior walls of the container, the switch module configured to switch signals transmitted to and received from the plurality of antennas via a plurality of channels, the VNA configured to measure scattering parameters (S-parameters) of all of the plurality of channels, the method comprising: de-embedding a combined effect of the measurement system based on a 2-port network de-embedding technique using only a subset of the S-parameters, wherein the de-embedding is based on modelling the measurement system; and providing an image of the commodity using an inversion algorithm based on input of a calibrated S-parameter after the de-embedding.

The modelling may be based at least partially on a series of cascaded 2-port sub-networks for each antenna pair, including a transmission switch channel, a first cable, a device under test (DUT) consisting of the container with the plurality of antennas, a second cable, and a receiving switch channel.

The modelling may include measuring and storing all 2-port S-parameters for all channels, for a range of temperatures, through the switch module when the switch module is not connected to the plurality of cables.

The switch module may include a plurality of amplifiers. The subset of the S-parameters may include S11 and S21 data. The modelling further may include measuring the S11 data over a defined frequency band for each antenna with a transmission amplifier among the plurality of amplifiers disengaged, determining an impulse response computed based on the S11 data measurements, determining lengths of the cable based on the impulse response; and modeling network parameters of the measurement system based further on specifications of the cable and lossy transmission equations.

Modelling further may include measuring S11 and S21 data for every antenna pair with the transmission amplifier engaged.

Modelling further may include estimating an S22 measurement for the measurement system by: removing the transmission switch channel from the S11 data measurements and approximating S11 data based on the first cable, the DUT, and the second cable; and removing the transmission switch channel from the S22 data measurements and approximating S22 data based on the first cable, the DUT, and the second cable.

Modelling may include determining S12 of the measurement system based on all of the 2-port S-parameters of the channels through the switching module, the cables, and the S11, S21, and S22 measurements.

The method may include converting the S-parameters to transmission parameters and performing a standard calibration.

The method may include converting bin measurements to S-parameters to obtain calibrated S21 data for use in the inversion algorithm.

Other technical features may be readily apparent to one skilled in the art from the following figures, descriptions, and claims.

Within the scope of this application it should be understood that the various aspects, embodiments, examples and alternatives set out herein, and individual features thereof may be taken independently or in any possible and compatible combination. Where features are described with reference to a single aspect or embodiment, it should be understood that such features are applicable to all aspects and embodiments unless otherwise stated or where such features are incompatible.

### BRIEF DESCRIPTION OF THE DRAWINGS

Many aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

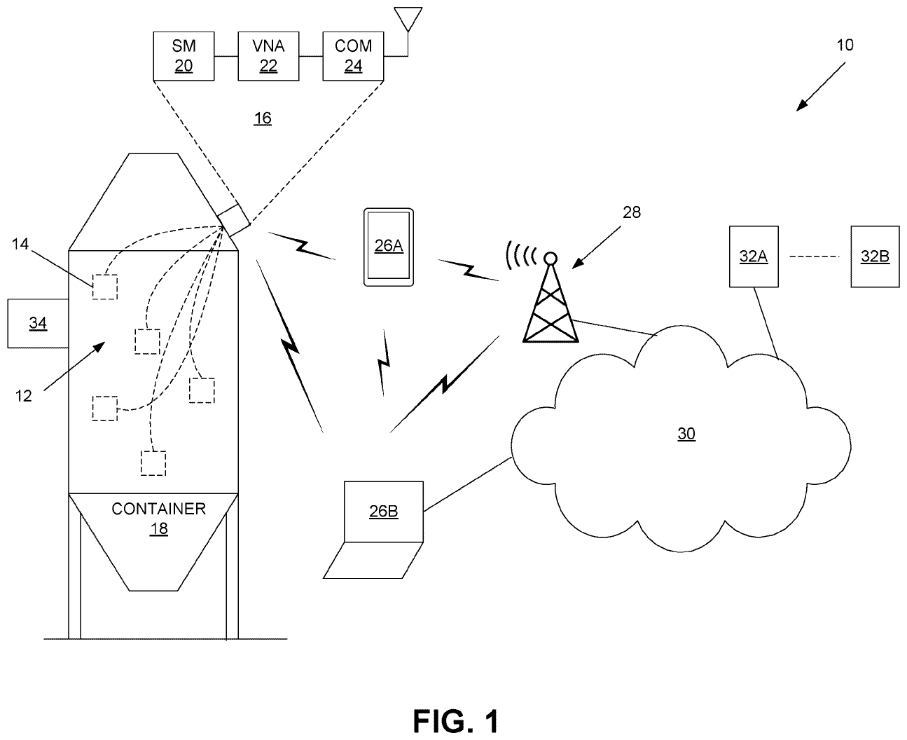

FIG. 1 is a schematic diagram that illustrates an example electromagnetic imaging (EMI) environment in which an embodiment of a de-embedding system may be implemented;

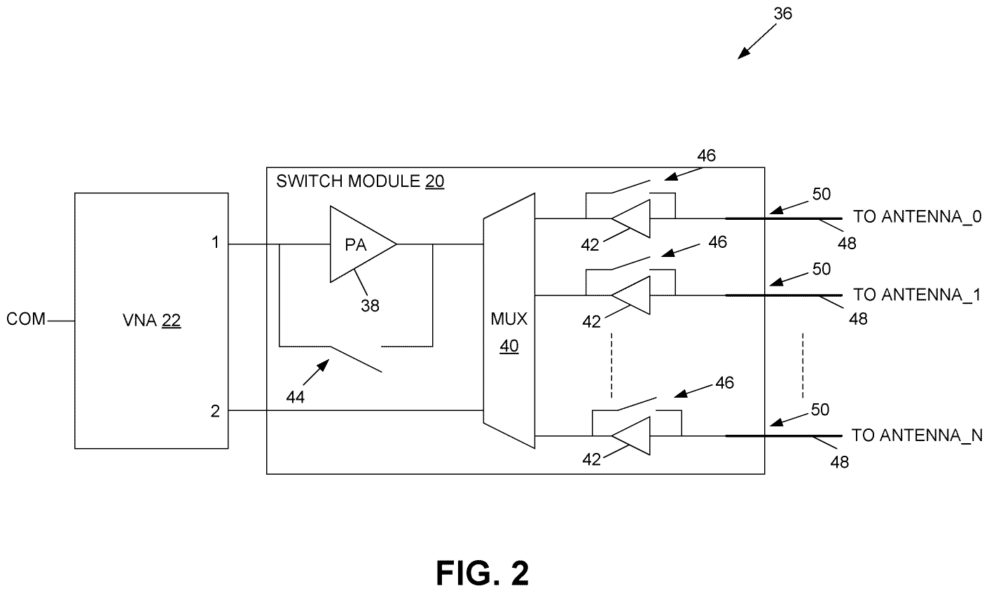

FIG. 2 is schematic diagram that illustrates an embodiment of a measurement system used in a de-embedding system;

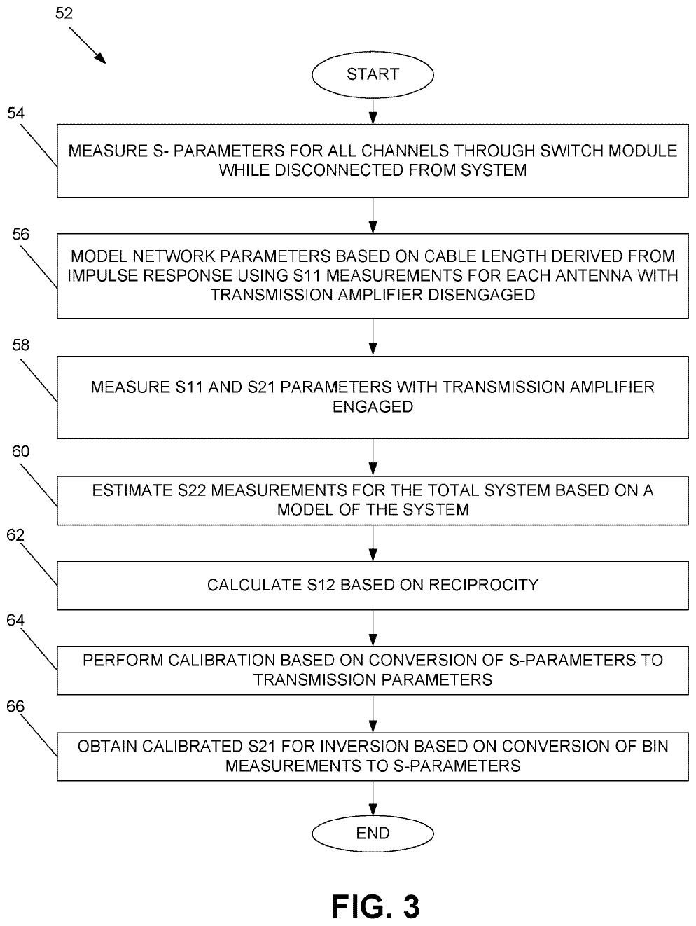

FIG. 3 is a flow diagram that illustrates an embodiment of a process by which a de-embedding system removes the effects of a switch module and cabling using a model;

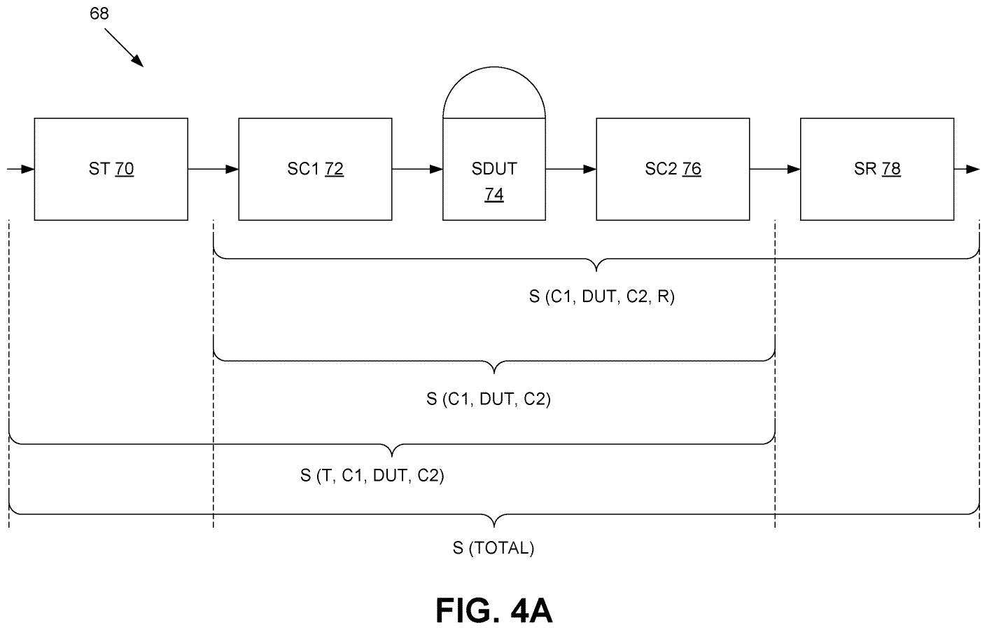

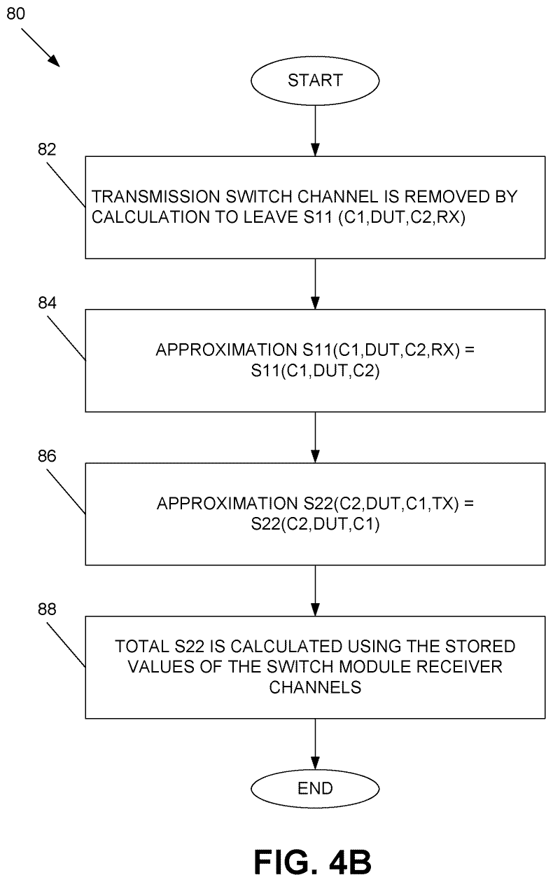

FIG. 4A is a schematic diagram that illustrates an embodiment of a model used in the process of FIG. 3;

FIG. 4B is a flow diagram that illustrates a process used with the model of FIG. 4A to estimate S12 and S22 parameters;

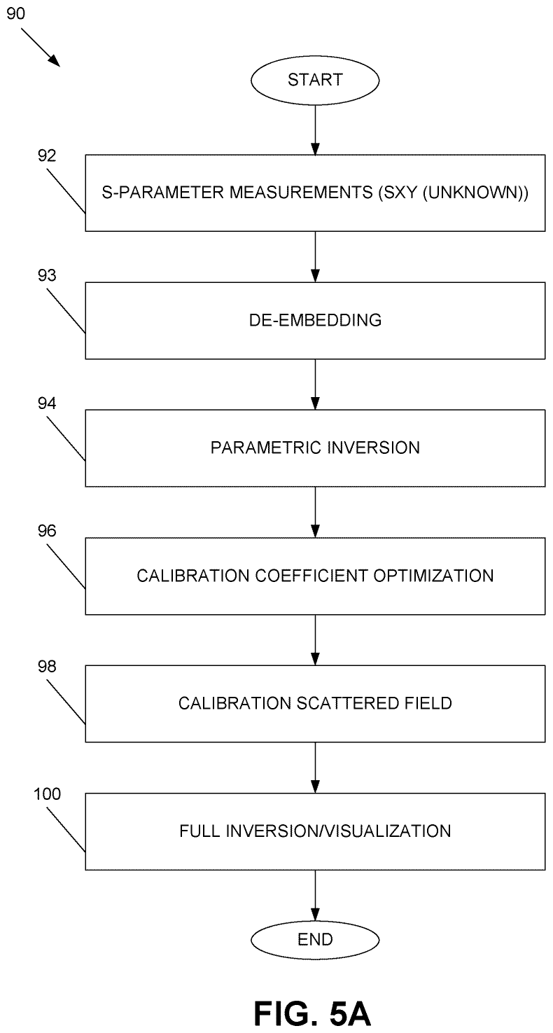

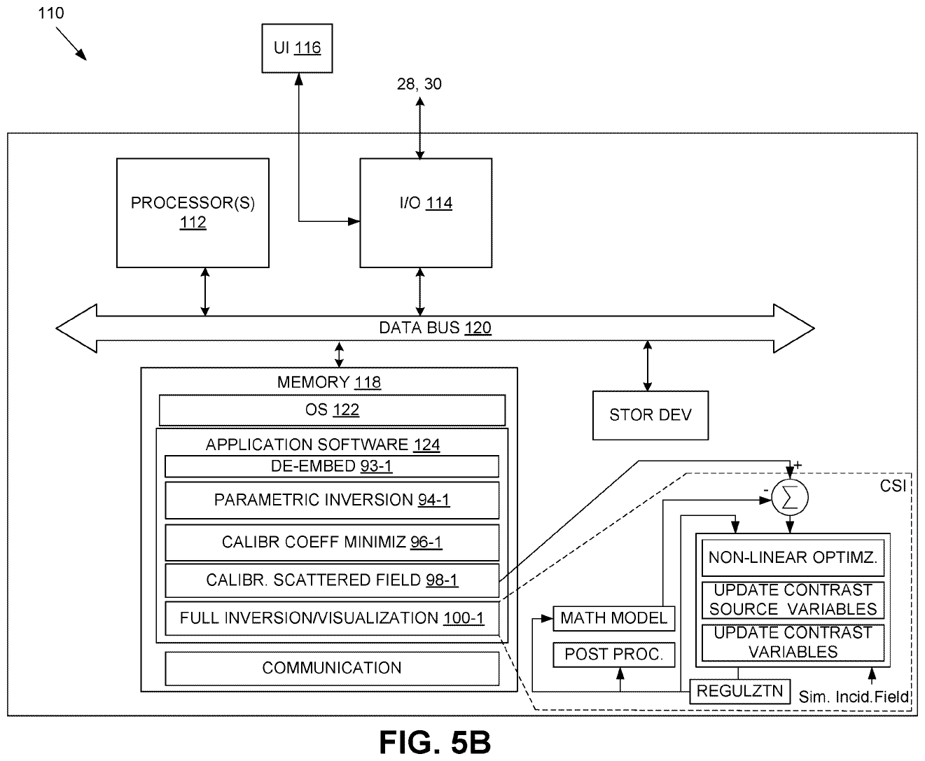

FIG. 5A is a logical block diagram that illustrates an embodiment of an example EMI process;

FIG. 5B is a block diagram that illustrates an example computing device that implements certain functionality of the EMI process of FIG. 5A; and

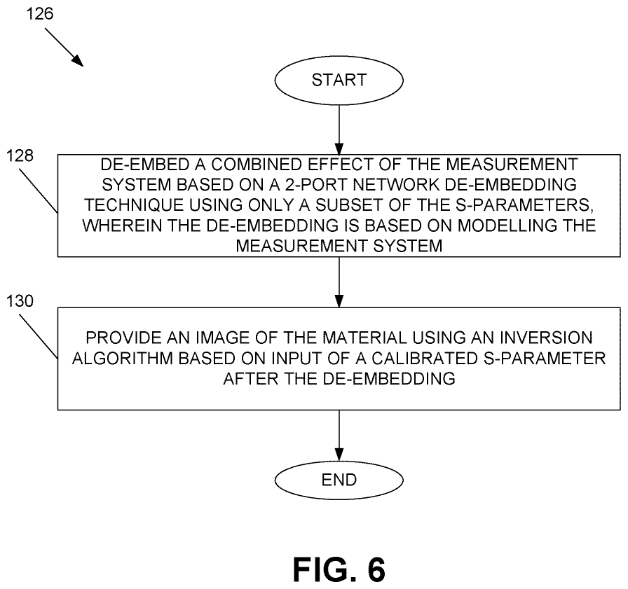

FIG. 6 is a flow diagram that illustrates an embodiment of a method for de-embedding a measurement system and imaging materials in a container.

### DETAILED DESCRIPTION

Illustrations presented herein are not meant to be actual views of any particular container, antenna, measurements system, component, or system, but are merely idealized representations that are employed to describe embodiments of the disclosure. Additionally, elements common between figures may retain the same numerical designation for convenience and clarity.

The following description provides specific details of embodiments. However, a person of ordinary skill in the art will understand that the embodiments of the disclosure may be practiced without employing many such specific details. Indeed, the embodiments of the disclosure may be practiced in conjunction with conventional techniques employed in the industry. In addition, the description provided below does not include all the elements that form a complete structure or assembly. Only those process acts and structures necessary to understand the embodiments of the disclosure are described in detail below. Additional conventional acts and structures may be used. The drawings accompanying the application are for illustrative purposes only, and are thus not drawn to scale.

As used herein, the terms “comprising,” “including,” “containing,” “characterized by,” and grammatical equivalents thereof are inclusive or open-ended terms that do not exclude additional, unrecited elements or method steps, but also include the more restrictive terms “consisting of” and “consisting essentially of” and grammatical equivalents thereof.

As used herein, the singular forms following “a,” “an,” and “the” are intended to include the plurality of forms as well, unless the context clearly indicates otherwise.

As used herein, the term “may” with respect to a material, structure, feature, or method act indicates that such is contemplated for use in implementation of an embodiment of the disclosure, and such term is used in preference to the more restrictive term “is” so as to avoid any implication that other compatible materials, structures, features, and methods usable in combination therewith should or must be excluded.

As used herein, the term “configured” refers to a size, shape, material composition, and arrangement of one or more of at least one structure and at least one apparatus facilitating operation of one or more of the structure and the apparatus in a predetermined way.

As used herein, any relational term, such as “first,” “second,” etc., is used for clarity and convenience in understanding the disclosure and accompanying drawings, and does not connote or depend on any specific preference or order, except where the context clearly indicates otherwise.

As used herein, the term “substantially” in reference to a given parameter, property, or condition means and includes to a degree that one skilled in the art would understand that the given parameter, property, or condition is met with a small degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the term “about” used in reference to a given parameter is inclusive of the stated value and has the meaning dictated by the context (e.g., it includes the degree of error associated with measurement of the given parameter, as well as variations resulting from manufacturing tolerances, etc.).

As used herein, the term “and/or” includes any and all combinations of one or more of the associated listed items.

### Overview

In one embodiment, a system comprising: a container configured to store material (e.g., a commodity); a measurement system comprising a vector network analyzer (VNA), a switch module, a plurality of cables, the container, and a plurality of antennas coupled to interior walls of the container, the switch module configured to switch signals transmitted to and received from the plurality of antennas via a plurality of channels, the VNA configured to measure scattering parameters (S-parameters) of all of the plurality of channels; a non-transitory computer readable medium comprising software; and a processor configured by the software to: de-embed a combined effect of the measurement system based on a 2-port network de-embedding technique using only a subset of the S-parameters; and provide an image of the material using an inversion algorithm based on input of a calibrated S-parameter after the de-embedding.

### Detailed Description

Certain embodiments of a de-embedding system and method are disclosed for an electromagnetic imaging (EMI) system comprising a measurement system that includes a Vector Network Analyzer (VNA) and a plurality of antennas and switching circuity for use in conjunction with measuring material (e.g., commodity) properties (e.g., moisture content) in containers (e.g., grain in storage containers or bins). In one embodiment, the EMI system uses a 2-port network de-embedding technique to remove switching and cable effects from a multi-port measurements system, where only the Scattering parameters (S-parameters), S11 and S21, of each measurement path are measured. As is explained further below, the only necessary inputs are the complete S-parameters of any network devices (e.g., a Vector Network Analyzer or VNA, and a switching module, in a partial VNA system), and the S11 and S21 measurements that are already being collected during system operations.

Digressing briefly, one significant issue with raw S21 data measurements from the VNA is that they include the effects of switching circuitry, cables, and other electronics in between the VNA and the antennas. As with all measurements, it is desirable to eliminate distortions caused by the measurement system. In this case, distortion from the cables is particularly an issue as industrial bins can be large (e.g., forty (40) meters in diameter). Cables of varying lengths are needed to reach every antenna scattered around the bin. The combined effect of the transmission/receiving channels and cables distort the true measurement taken at the antenna port, often leading to the need for de-embedding.

In an effort to eliminate the effects of the cables, switch, etc., certain embodiments of a de-embedding system use a 2-port network de-embedding technique, and in the described example embodiments, transmission matrices (e.g., ABCD matrices), despite the fact that partial VNAs present distinct challenges (e.g., since 2-port network analysis techniques require the full 2-port parameters of all sub-networks). Certain embodiments of de-embedding systems and methods described herein use only the S11 and S21 measurement data while estimating the remaining S-parameters. In effect, the de-embedding system provides a method of calibrating the data, removing the effects of the switching channels and cables from the true measurements taken at the antenna. This approach addresses a problem of the need in established calibration techniques to determine full network characterizations of each measurement path or for each path to be connected to a calibration device, neither of which are feasible for a grain bin in the field. The use of the de-embedding system and method of the disclosed embodiments improves accuracy in the outcomes of the EMI results while reducing the time and resources involved in calibration as compared to conventional systems.

Having summarized certain features of a de-embedding system of the present disclosure, reference will now be made in detail to the description of a de-embedding system as illustrated in the drawings. While a de-embedding system will be described in connection with a partial VNA system that measures properties of grain, there is no intent to limit it to the embodiment or embodiments disclosed herein. For instance, certain features of a de-embedding system may be used in any multi-port measurement system where only the S11 and S21 parameters of each measurement path are measured, and/or for material other than grain (e.g., granular material or fluid) as long as such contents reflect electromagnetic waves. Further, although the description identifies or describes specifics of one or more embodiments, such specifics are not necessarily part of every embodiment, nor are all various stated advantages necessarily associated with a single embodiment or all embodiments. On the contrary, the intent is to cover all alternatives, modifications and equivalents included within the spirit and scope of the disclosure as defined by the appended claims. Further, it should be appreciated in the context of the present disclosure that the claims are not necessarily limited to the particular embodiments set out in the description, and that different embodiments described herein may be combined in any combination.

FIG. 1 is a schematic diagram that illustrates an example EMI environment 10 in which an embodiment of a de-embedding system may be implemented. It should be appreciated by one having ordinary skill in the art in the context of the present disclosure that the environment 10 is one example among many, and that some embodiments of a de-embedding system may be used in environments with fewer, greater, and/or different components than those depicted in FIG. 1. The environment 10 comprises a plurality of devices that enable communication of information throughout one or more networks. The depicted environment 10 comprises an antenna array 12 comprising a plurality of antennas (e.g., antenna probes) 14 and a system 16 that is used to monitor/measure material within a container 18 and uplink with other devices to communicate and/or receive information. The container 18 is depicted as one type of grain storage bin (or simply, grain bin or bin), though it should be appreciated that containers of other geometries, for the same or other material (e.g., grain or other material), with a different arrangement (side ports, etc.) and/or quantity of inlet and outlet ports, may be used in some embodiments. As is known, electromagnetic imaging uses active transmitters and receivers of electromagnetic radiation to obtain quantitative and qualitative images of a complex dielectric profile of an object of interest (e.g., here, the material or grain).

As shown in FIG. 1, multiple antenna probes 14 of the antenna array 12 are mounted along the interior of the container 18 in a manner that surrounds the contents of the container 18 to effectively collect the scattered signal. For instance, each transmitting antenna probe is polarized to excite/collect the signals scattered by the material. That is, each antenna probe 14 illuminates the material while the receiving antennas probes collected the signals scattered by the material. In one embodiment, the antennas 14 comprise shielded half-loop antennas. In one embodiment, the system 16 comprises a switch module (SM) 20, a vector network analyzer (VNA) 22, and a communications module (COM) 24. The antenna probes 14 are connected (via cabling, such as coaxial cabling) to the switch module 20. The switch module 20 is coupled to the VNA 22. The VNA 22 is coupled to the communications module 24. The VNA 22 comprises electromagnetic transceiver circuitry that generates radio frequency (RF) signals. The RF signals are transmitted through, and switched by, the switch module 20, to the antennas 14 of the antenna array 12 that are connected to the switch module 20 via cabling. The switched RF signals are used to excite the antennas 14 for imaging of the contents of the container 18. The switch module 20 switches between the transmitter/receiver pairs. The reflected signal is received by the VNA 22, via the switch module 20 (and cabling), where the VNA 22 is used to measure scattering parameters (S-parameters) corresponding to the electromagnetic fields generated at the antennas 14 and used to image the material stored in the container 18. In effect, the VNA 22 and switch module 20 enables each antenna probe 14 to deliver RF energy to the container 18 and collect the RF energy from the other antenna probes 14. The VNA 22 is coupled to the communications module 24, which includes transceiver circuitry (e.g., cellular and/or radio modem), the communications module 24 configured to communicate the measurements performed by the VNA 22 to, in some embodiments, a remote network for data processing and analysis. As the arrangement and operations of the antenna array 12 and system 16 are known, further description is omitted here for brevity. Additional information may be found in the publications “Industrial scale electromagnetic grain bin monitoring”, Computers and Electronics in Agriculture, 136, 210-220, Gilmore, C., Asefi, M., Paliwal, J., & LoVetri, J., (2017), “Surface-current measurements as data for electromagnetic imaging within metallic enclosures”, IEEE Transactions on Microwave Theory and Techniques, 64, 4039, Asefi, M., Faucher, G., & LoVetri, J. (2016), and “A 3-d dual-polarized near-field microwave imaging system”, IEEE Trans. Microw. Theory Tech., Asefi, M., OstadRahimi, M., Zakaria, A., LoVetri, J. (2014).

Note that in some embodiments, the system 16 may include additional circuitry, including a global navigation satellite systems (GNSS) device or triangulation-based devices, which may be used to provide location information to another device or devices within the environment 10 that remotely monitors the container 18 and associated data. The system 16 may include suitable communication functionality to communicate with other devices of the environment.

The uncalibrated, raw data collected from the system 16 is communicated (e.g., via uplink functionality of the communications module 24) to one or more electronic devices of the environment 10, including electronic devices 26A and/or 26B. Communication by the system 16 may be achieved using near field communications (NFC) functionality, Blue-tooth functionality, 802.11-based technology, satellite technology, streaming technology, including LoRa, and/or broadband technology including 3G, 4G, 5G, etc., and/or via wired communications (e.g., hybrid-fiber coaxial, optical fiber, copper, Ethernet, etc.) using TCP/IP, UDP, HTTP, DSL, among others. The electronic devices 26A and 26B communicate with each other and/or with other devices of the environment 10 via a wireless/cellular network 28 and/or wide area network (WAN) 30, including the Internet. The wide area network 30 may include additional networks, including an Internet of Things (IoT) network, among others. Connected to the wide area network 30 is a computing system comprising one or more computing devices including servers 32 (e.g., 32A, . . . 32N).

The electronic devices 26 may be embodied as a smartphone, mobile phone, cellular phone, pager, stand-alone image capture device (e.g., camera), laptop, tablet, personal computer, workstation, among other handheld, portable, or other computing/communication devices, including communication devices having wireless communication capability, including telephony functionality. In the depicted embodiment of FIG. 1, the electronic device 26A is illustrated as a smartphone and the electronic device 26B is illustrated as a laptop for convenience in illustration and description, though it should be appreciated that the electronic devices 26 may take the form of other types of devices as explained above.

The electronic devices 26 provide (e.g., relay) the (uncalibrated, raw) data sent by the system 16 to one or more servers 32 via one or more networks. The wireless/cellular network 28 may include the necessary infrastructure to enable wireless and/or cellular communications between the electronics device 26 and the one or more servers 32. There are a number of different digital cellular technologies suitable for use in the wireless/cellular network 28, including: 3G, 4G, 5G, GSM, GPRS, CDMAOne, CDMA2000, Evolution-Data Optimized (EV-DO), EDGE, Universal Mobile Telecommunications System (UMTS), Digital Enhanced Cordless Telecommunications (DECT), Digital AMPS (IS-136/TDMA), and Integrated Digital Enhanced Network (iDEN), among others, as well as Wireless-Fidelity (Wi-Fi), 802.11, streaming, etc., for some example wireless technologies.

The wide area network 30 may comprise one or a plurality of networks that in whole or in part comprise the Internet. The electronic devices 26 may access the one or more server 32 via the wireless/cellular network 28, as explained above, and/or the Internet 30, which may be further enabled through access to one or more networks including PSTN (Public Switched Telephone Networks), POTS, Integrated Services Digital Network (ISDN), Ethernet, Fiber, DSL/ADSL, Wi-Fi, among others. For wireless implementations, the wireless/cellular network 28 may use wireless fidelity (Wi-Fi) to receive data converted by the electronic devices 26 to a radio format and process (e.g., format) for communication over the Internet 30. The wireless/cellular network 28 may comprise suitable equipment that includes a modem, router, switching circuits, etc.

The servers 32 are coupled to the wide area network 30, and in one embodiment may comprise one or more computing devices networked together, including an application server(s) and data storage. In one embodiment, the servers 32 may serve as a cloud computing environment (or other server network) configured to perform processing required to implement an embodiment of a de-embedding system as well as pixel-based inversion. When embodied as a cloud service or services, the server 32 may comprise an internal cloud, an external cloud, a private cloud, a public cloud (e.g., commercial cloud), or a hybrid cloud, which includes both on-premisess and public cloud resources. For instance, a private cloud may be implemented using a variety of cloud systems including, for example, Eucalyptus Systems, VMWare vSphere®, or Microsoft® HyperV. A public cloud may include, for example, Amazon EC2®, Amazon Web Services®, Terremark®, Savvis®, or GoGrid®. Cloud-computing resources provided by these clouds may include, for example, storage resources (e.g., Storage Area Network (SAN), Network File System (NFS), and Amazon S3®), network resources (e.g., firewall, load-balancer, and proxy server), internal private resources, external private resources, secure public resources, infrastructure-as-a-services (IaaSs), platform-as-a-services (PaaSs), or software-as-a-services (SaaSs). The cloud architecture of the servers 32 may be embodied according to one of a plurality of different configurations. For instance, if configured according to MICROSOFT AZURE™, roles are provided, which are discrete scalable components built with managed code. Worker roles are for generalized development, and may perform background processing for a web role. Web roles provide a web server and listen for and respond to web requests via an HTTP (hypertext transfer protocol) or HTTPS (HTTP secure) endpoint. VM roles are instantiated according to tenant defined configurations (e.g., resources, guest operating system). Operating system and VM updates are managed by the cloud. A web role and a worker role run in a VM role, which is a virtual machine under the control of the tenant. Storage and SQL services are available to be used by the roles. As with other clouds, the hardware and software environment or platform, including scaling, load balancing, etc., are handled by the cloud.

In some embodiments, the servers 32 may be configured into multiple, logically-grouped servers (run on server devices), referred to as a server farm. The servers 32 may be geographically dispersed, administered as a single entity, or distributed among a plurality of server farms. The servers 32 within each farm may be heterogeneous. One or more of the servers 32 may operate according to one type of operating system platform (e.g., WINDOWS-based O.S., manufactured by Microsoft Corp. of Redmond, Wash.), while one or more of the other servers 32 may operate according to another type of operating system platform (e.g., UNIX or Linux). The group of servers 32 may be logically grouped as a farm that may be interconnected using a wide-area network connection or medium-area network (MAN) connection. The servers 32 may each be referred to as, and operate according to, a file server device, application server device, web server device, proxy server device, and/or gateway server device.

In one embodiment, one or more of the servers 32 may comprise a web server that provides a web site that can be used by users interested in the contents of the container 18 via browser software residing on an electronic device (e.g., electronic device 26). For instance, the web site may provide visualizations that reveal permittivity of the contents and/or geometric and/or other information about the container and/or contents (e.g., the volume geometry, such as cone angle, height of the grain along the container wall, etc.).

The functions of the servers 32 described above are for illustrative purpose only. The present disclosure is not intended to be limiting. For instance, functionality for performing de-embedding and/or pixel-based inversion may be implemented at a computing device that is local to the container 18 (e.g., edge computing), or in some embodiments, such functionality may be implemented at the electronic device(s) 26. In some embodiments, functionality of the de-embedding method and/or pixel-based inversion described herein may be implemented in different devices of the environment 10 operating according to a primary-secondary configuration or peer-to-peer configuration. In some embodiments, the system 16 may bypass the electronic devices 26 and communicate with the servers 32 via the wireless/cellular network 28 and/or the wide area network 30 using suitable processing and software residing in the system 16.

Note that cooperation between the electronic devices 26 (or in some embodiments, the system 16) and the one or more servers 32 may be facilitated (or enabled) through the use of one or more application programming interfaces (APIs) that may define one or more parameters that are passed between a calling application and other software code such as an operating system, a library routine, and/or a function that provides a service, that provides data, or that performs an operation or a computation. The API may be implemented as one or more calls in program code that send or receive one or more parameters through a parameter list or other structure based on a call convention defined in an API specification document. A parameter may be a constant, a key, a data structure, an object, an object class, a variable, a data type, a pointer, an array, a list, or another call. API calls and parameters may be implemented in any programming language. The programming language may define the vocabulary and calling convention that a programmer employs to access functions supporting the API. In some implementations, an API call may report to an application the capabilities of a device running the application, including input capability, output capability, processing capability, power capability, and communications capability.

An embodiment of a de-embedding system may include any one or a combination of the components of the environment 10. For instance, in one embodiment, the de-embedding system may include a single computing device (e.g., one of the servers 32 or one of the electronic devices 26, or an edge computing device), and in some embodiments, the de-embedding system may comprise the container 18, the antenna array 12, the system 16, and one or more of the server(s) 32 and electronic devices 20, or in some embodiments, the antenna array 12, the system 16, and one or more of the server(s) 32 and electronic devices 20. For purposes of illustration and convenience, implementation of an embodiment of a de-embedding method is described in the following as being implemented in a computing device that may be one of the servers 32, with the understanding that functionality may be implemented in other and/or additional devices. Also shown in FIG. 1 is a moisture-affecting device 34 (e.g., a fan, blower, etc.), operably coupled (e.g., directly mounted, ducted, etc.) to the container 18, and that may be activated by one of the devices (e.g., server 32, electronic device 26) based on a determination of the moisture content within the container 18 (e.g., if there is too much moisture in the grain). Though a single moisture-affecting device 34 is shown, there may be a plurality of such devices.

In one example operation, a user (via the electronic device 26) requests measurements of the contents of the container 18. This request is communicated to the system 16. In some embodiments, the triggering of measurements may occur automatically based on a fixed time frame or based on certain conditions or based on detection of an authorized user (electronic) device 26. In some embodiments, the request may trigger the communication and/or retrieval of measurements that have already occurred. The system 16 activates (e.g., excites) the antenna probes 14 of the antenna array 12, such that the system (via the transmission of signals and receipt of the scattered signals) collects a set of raw, uncalibrated electromagnetic data at a set of (a plurality of) discrete, sequential frequencies (e.g., 10-100 Mega-Hertz (MHz), though not limited to this range of frequencies nor limited to collecting the frequencies in sequence). In one embodiment, the uncalibrated data comprises S-parameter measurements (which are used to generate a background model or information as described below). The de-embedding system may use the un-calibrated raw data and calibrated data (e.g., from measurements taken when the VNA 24 and switch module 20 are disconnected from the antennas, such as before installation (e.g., at the factory that provides the de-embedding system or certain components thereof) or in the field, yet disconnected).

As is known, S-parameters are ratios of voltage levels (e.g., due to the decay between the sending and receiving signal). Though S-parameter measurements are described, in some embodiments, other mechanisms for describing voltages on a line may be used. For instance, power may be measured directly (without the need for phase measurements), or various transforms may be used to convert S-parameter data into other parameters, including transmission parameters, impedance, admittance, etc. Since the uncalibrated S-parameter measurement is corrupted by the switching module 20 and/or varying lengths and/or other differences (e.g., manufacturing differences) in the cables connecting the antenna probes 14 to the system 16, it is important that certain embodiments of the de-embedding system and method to be implemented to remove the switching and cable effects from the S-parameter measurements as they corrupt the desired signal from the antenna port. As described further below, the de-embedding system performs the de-embedding method using only a subset of the entire S-parameter data (e.g., the subset consisting of S11 and S21 data, not the full set that also requires S12 and S22). The system 16 communicates (e.g., via a wired and/or wireless communications medium) the uncalibrated (S-parameter) data to the electronic device 26, which in turn communicates the uncalibrated data to the server 32. At the server 32, de-embedding and other EMI processing (e.g., inversion) are performed as explained further below.

FIG. 2 is a schematic diagram of an embodiment of a measurement system 36 used in a de-embedding system. The measurement system 36 comprises the VNA 22 and the switch module 20 with ports enabling cabling (e.g., coaxial cables) to connect to the plurality of antennas 14 of the antenna array 12 (FIG. 1). The antennas 14 and container 18 are omitted here to avoid obfuscating certain relevant features. In other words, the measurement system 36 may comprise the VNA 22, the switch module 20, the antennas 14, and the container 18 shown in FIG. 1. The VNA 22 comprises a radio frequency (RF) signal source that operates according to a frequency range (e.g., 1-1300 mega Hertz (MHz), though not limited to this range), and comprises two ports, Port 1 and Port 2 for transmitting and receiving electromagnetic signals. The VNA 22 also measures the electromagnetic fields reflected from the antennas 14. The VNA 22 is a partial VNA, meaning that the VNA 22 measures only a subset of the S-parameters, namely, S11 and S21 parameters. As VNAs (and partial VNAs) are generally known in the industry, further discussion of the same is omitted here for brevity.

The switch module 20 comprises a power or transmission amplifier 38, a 2 to N multiplexer (MUX) 40, and a plurality of receive amplifiers 42 (e.g., low noise amplifiers). The power amplifier 38 is depicted as connected between Port 1 of the VNA 22 and the MUX 40. A switch 44 is arranged in parallel with the power amplifier 38. The MUX 40 is connected on the 2-port side to the parallel arrangement of the power amplifier 38 and the switch 44, and Port 2 of the VNA 22. On the N-port side of the MUX 40, the MUX is connected to the plurality of (N) receive amplifiers 42, which are each connected between the MUX 40 and cabling (coaxial cabling) 48 that connects, through ports 50 of the switch module 20, to the plurality of antennas 14 (e.g., antenna_0, antenna_1, . . . antenna_N, actual antennas not shown, wherein one embodiment, N equals 24, though other quantities of antennas may be used for an antenna array 12 in some embodiments). Each of the plurality of receive amplifiers 42 are arranged in parallel with a switch 46.

The antennas 14 are attached to the interior wall of the container 18 to enable the transmission and measurement of electromagnetic waves. The measured signals are sent through the cables 48 and switch module 20 (to be measured by the VNA 22). The switch module 20 provides different channels to connect the VNA 22 to each antenna 14. A channel, as used in the disclosure, refers to the signal path taken from signal transmission from the VNA 22 to signal reception at the VNA 22, and includes the path taken through the switch module 20, the cabling 48, and the antennas 14 and container 18. In an example operation, the VNA 22 makes measurements by comparing the signal transmitted out of Port 1 of the VNA 22 to the received signal received at Port 1 (S11) and Port 2 (S21). When a channel is transmitting, the power amplifier 38 is engaged (e.g., turned or toggled on), and the signal connection is completed through the MUX 40, bypasses the receive amplifier 42 via the switch 46 (hence toggling the receive amplifier off), and reaches an antenna 14. When receiving, the signal follows the path through the receiver amplifier 42, through the MUX 40, and to the Ports 1 and 2.

One goal underlying the de-embedding system is calibration of the measurement system 36 by calculating the signals at the antennas 14, rather than the signals at the VNA 22 that have been altered by transmission through the cables 48 and the switch module 20. As described above, certain embodiments of a de-embedding system provide a method of calibrating the data, removing the effects of the switch module channels and cables from the true measurements taken at the antenna. This approach is needed because established calibration techniques require full network characterizations of each measurement path or for each path to be connected to a calibration device, neither of which are feasible for, say, a grain bin in the field.

With continued reference to FIGS. 1-2, attention is directed to FIG. 3, which illustrates an embodiment of a process 52 by which a de-embedding system removes the effects of the switch module 20 and cabling 48 using a model. For instance, the process may 52 be implemented in a computing device or devices in the EMI environment 10 of FIG. 1, using measurement data from the measurement system 36 (FIG. 2). The process 52 comprises measuring S-parameters for all channels through the switch module 20 while disconnected from the system (54). For instance, prior to installation, the full S-parameters of all channels through the switch module 20 may be measured and stored. This is repeated for a range of temperatures to build a model for different conditions. In some instances, the switch module 20 may be installed in the field, yet disconnected from the cabling 48 and antennas 14 to measure the S-parameters. This data is generally recorded once, and then used in all subsequent de-embedding processes (e.g., for subsequent raw data sets measured during operations).

For each antenna pair, the process 52 further comprises the following steps 56-64. In some embodiments, the process 52 is performed for each antenna pair for other ranges of steps (e.g., for steps 56-62). Referring to step 56, the process 52 comprises modelling network parameters based on a cable length derived from an impulse response using S11 measurements for each antenna 14 with the transmission (power) amplifier 38 disengaged (56). For instance, an S11 measurement is taken over a wide frequency band for each antenna 14 with the power amplifier 38 disengaged (e.g., turned off or bypassed), which disengagement may be implemented using the switch 44 to bypass the power amplifier. An impulse response, which represents the time domain signal received back when a pulse is transmitted, is calculated by taking the inverse Fourier Transform of the S11 measurements. The time it takes for the pulse to transmit down the cable 48, reflect off the antenna 14, and propagate back is proportional to the cable length. For instance, the length of the cable is known as a function of the speed of light in free space (c), a velocity factor (v) through the cable (obtained from specifications of the cable manufacturer), and the propagation time of the signal through the cable (tp), or L=tp*c*v/2. Once this length is known, it can be used with other cable specifications from the datasheet to model the network parameters using the well-known lossy transmission line equations. Explaining further, the cables 48 are cut to size in the field and directly installed, so unlike the switch module 20, prior measurement is not possible. Instead, the cable length is estimated by taking the S11 measurement (with the transmit amplifier bypassed) and calculating the impulse response. The high antenna reflectivity results in a primary reflection spike at twice the cable length. Full 2-port cable parameters may then be estimated from known lossy transmission line equations (e.g., see S. Ramo, J. R. Whinnery, and T. Van Duzer, Fields and waves in communication electronics. John Wiley & Sons, 1994.) using the recovered cable length and cable datasheet values. Also, reference is made to the on-line article, “Transmission Line Transfer Function From ABCD and S-Parameters”, by Zacharia Peterson, created on Oct. 23, 2020 and updated on Feb. 11, 2021, though other resources may be used.

The process 52 further comprises measuring S11 and S21 parameters with the transmission amplifier 38 engaged (58). For instance, with the transmission (power) amplifier 38 turned back on (and/or the switch 44 opened), the standard S11 and S21 S-parameter measurements are taken between every antenna pair. In one example implementation, there may be twenty-four antennas 14 used, which results in twenty-four S11 measurements, and five hundred fifty-two S21 measurements. Note that the quantity of twenty-four is merely for illustrative and non-limiting purposes, and that other quantities may be used.

The process 52 further comprises estimating S22 measurements for the total system based on a model of the system (60). In one embodiment, the model may be represented schematically in FIG. 4A, denoted as model 68. The total system may be modelled as a series of cascaded sub-networks, including a switch module transmission channel (ST) 70, the first cable (SC1) 72, a grain bin (e.g., container 18) with antennas (S-parameter for device under test or SDUT) 74, the second cable (SC2) 76, and the receiving switch module channel (SR) 78. A particular combination of sub-networks is shown in respective brackets beneath the model 68 by “S” followed parenthetically with the particular sub-network combination. An embodiment of a process 80 for estimating S22 measurements based on the model 68 is depicted in FIG. 4B, and explains the illustration depicted for the model 68 in FIG. 4A. Before explaining the process 80 and model 68, it bears noting that the process 80 is based on a 2-port network de-embedding technique, knowledge of the intrinsic impedance of the system (e.g., fifty (50) ohms in the present example), and for illustration, ABCD matrices, though other 2-port network de-embedding techniques may be used in some embodiments. Digressing briefly, note that there are several different representations of 2-port networks that are interchangeable among one another, including S-Parameters, impedance parameters, or admittance parameters. Each involves a 2×2 matrix and fully characterizes a 2-port network (relating voltages and currents for each port). Continuing, if the ports of the VNA 22 are calibrated and the 2-port networks for the switch module 20 and cables 48 are known, the DUT may be de-embedded using ABCD matrices as follows:

$${[ \begin{matrix}AD \\ CD\end{matrix} ]}_{DUT} = {{{{{[ \begin{matrix}AB \\ CD\end{matrix} ]}_{C 1}^{- 1} [ \begin{matrix}AB \\ CD\end{matrix} ]}_{T}^{- 1} [ \begin{matrix}AB \\ CD\end{matrix} ]}_{total} [ \begin{matrix}AB \\ CD\end{matrix} ]}_{R}^{- 1} [ \begin{matrix}AB \\ CD\end{matrix} ]}_{C 2}^{- 1} .$$

This approach has two problems. As mentioned above, the VNA 22 is a partial VNA, and hence only measures S11 and S21. Thus, there is a need to determine how to obtain ABCD (total), and the ABCD parameters of the transmit and receive sub-networks need to be estimated. Note that the matrices for each sub-network are denoted using ABCD and, parenthetically, the sub-network (e.g., ABCD (DUT)).

The S22 parameter is calculated by considering the channels that measure each antenna pair in both directions. Although the channels through the switch module differ, they share the same central, reciprocal C1-DUT-C2 sub-network. Starting from S11, the following equation removes the transmission switch from the total system, where ABCD (T) are the transmission parameters of the transmission switch channel, and ZO is the system characteristic impedance:

$${S}_{11}^{C 1 , B , C 2 , R} = \frac{- {A}_{T} ( 1 - {S}_{11}^{total} ) - \frac{{B}_{T}}{{Z}_{0}} ( 1 - {S}_{11}^{total} ) + {Z}_{0} {C}_{T} ( 1 + {S}_{11}^{total} ) + {D}_{T} ( 1 + {S}_{11}^{total} )}{{A}_{T} ( 1 - {S}_{11}^{total} ) - \frac{{B}_{T}}{{Z}_{0}} ( 1 - {S}_{11}^{total} ) - {Z}_{0} {C}_{T} ( 1 + {S}_{11}^{total} ) + {D}_{T} ( 1 + {S}_{11}^{total} )}$$

Thus, referring to the process 80 of FIG. 4B (and the top bracket of FIG. 4A), starting from the total S11 measurements, the transmission switch channel (ST, which is S11T for the S11 measurements) is removed by calculation of the equation immediately above to leave S11 (C1,DUT,C2,RX) (82). Note that there is no intended difference substantively between use of subscripts or superscripts in some instances (e.g., in the formulas), and non-use of the same in the description, and non-use is merely out of formatting convenience. For instance S11 is intended to be the same as S11.

The approximation S11 (C1,DUT,C2,RX)=S11 (C1,DUT,C2) is made (84), as also shown in the second bracket from the top in FIG. 4A. Essentially, this approximation is based on the premise or assumption that the switch module channel on the opposite side of the antenna that is being measured (e.g., where the antenna pairs are on opposite side locations of the storage bin/container) has no effect. Any signal that reaches the opposite or far side and reflects back is so small that its measurement is inconsequential (e.g., because the high path loss and antenna reflection causes no significant reflection off of the receiver switch to reach back to the transmitter side).

From its definition, the S11 measurement into a two-port network is the same as the S22 when the device orientation is flipped. For instance, the S11 measurement may take the path of Port 1 from the VNA 22, through the switch module 20 and cabling 48 to antenna_0, and then reflected back through the cabling 48, switch module 20, and to Port 1. For an S21 measurement, the signal may go from Port 1 of the VNA 22, through the switch module 20, to antenna_0, triangle, to another antenna (e.g., antenna_1 as it travels through the material of the storage container 18), and back through the switch module 20 to Port 2. An S12 measurement may be based on the signal transmitted from port 2 and received at 1, and as explained above, S21 may be based on the signal transmitted from Port 1 and received at Port 2. When the device orientation is flipped, S22 takes a similar path as S11. Notably, reciprocity in electromagnetics basically equates S12 with S21 for non-linear, isotropric systems. Accordingly, a similar process is used to determine Stotal 22. The addition of the transmission switch on the opposite side has no effect, and Stotal 22 is calculated using the following equation, where ABCD(R) are the transmission parameters of the receiver switch channel:

$${S}_{22}^{total} = \frac{\begin{matrix}- {A}_{R} ( 1 - {S}_{22}^{T , C 1 , DUT , C 2} ) + \frac{{B}_{B}}{{Z}_{0}} ( 1 - {S}_{22}^{T , C 1 , DUT , C 2} ) - \\ {Z}_{0} {C}_{R} ( 1 + {S}_{22}^{T , C 1 , DUT , C 2} ) + {D}_{R} ( 1 + {S}_{22}^{T , C 1 , DUT , C 2} )\end{matrix}}{\begin{matrix}{A}_{R} ( 1 - {S}_{22}^{T , C 1 , DUT , C 2} ) + \frac{{B}_{B}}{{Z}_{0}} ( 1 - {S}_{22}^{T , C 1 , DUT , C 2} ) + \\ {Z}_{0} {C}_{R} ( 1 + {S}_{22}^{T , C 1 , DUT , C 2} ) + {D}_{R} ( 1 + {S}_{22}^{T , C 1 , DUT , C 2} )\end{matrix}}$$

Referring to the process 80 (and the third bracket from the top of the brackets shown in FIG. 4A), the process is now reversed, where the approximation S22 (C2,DUT,C1,TX)=S22 (C2,DUT,C1) is used to add the switch module channel on the opposite side (86).

Finally, using the stored values of the switch module receiver channels, the total S22 is calculated (88), as also illustrated by the bottom bracket in FIG. 4A.

Referring again to FIG. 3, the process 52 further comprises (e.g., for each antenna pair) calculating S12 based on reciprocity (62). The S12 of the total system can be calculated based on the full parameters of the cables, switch module channels, and the total system S11, S21, and S22 measurements. This is possible by assuming the DUT sub-network is reciprocal, so the transmission is the same in both directions.

The process 52 further comprises performing calibration based on conversion (e.g., using known or standard formulas) of the S-parameters to transmission (ABCD) parameters (64), and obtaining a calibrated S21 for inversion based on conversion of bin measurements to S-parameters (66). That is, the S-parameters are converted to transmission parameters, and standard calibration (e.g., calibration that is equivalent to characterizing every channel in, say, a controlled setting, such as a laboratory) is now done by matrix multiplication. The bin measurements are converted back to S-parameters to obtain the calibrated S21 parameter/data to use in an inversion algorithm. As is known, the different types of parameters merely represent the network(s) with a different combinations of voltages and currents, where some parameter types are chosen over others based on the ease in computation for various steps (e.g., S-parameters facilitate measurements, whereas transmission parameters facilitate computations for cascaded networks or sub-networks). In some embodiments, the steps above may be modified using different parameter types.

Having described certain embodiments of a de-embedding process, attention is directed to FIG. 5A, which shows an embodiment of an EMI process 90 in which de-embedding may be implemented. The EMI process 90 may be implemented in the environment 10 of FIG. 1, with the inversion and de-embedding implemented in one or more devices, such as a the server(s) 26. Blocks 92-100 in FIG. 5A collectively provide a logical flow diagram and that are intended to represent modules of code (e.g., opcode, machine language code, higher level code), fixed or programmable hardware, or a combination of both that implement the functionality or method step of each block, where all blocks may be implemented in a single component or device or implemented using a distributed network of components or devices. It should be appreciated by one having ordinary skill in the art, in the context of the present disclosure, that in some circumstances, de-embedding may not be implemented. For instance, in some cases where the processing of the complex S-parameters results in an introduction of excessive noise, for especially the phase aspects when de-embedding is implemented, de-embedding may be disabled.

Continuing, the process 90 comprises S-parameter measurements (92), de-embedding (93), parametric inversion (94), calibration coefficients optimization (96), calibrated scattered field (98), and full inversion/visualization (100). For S-parameter measurements, raw data from bin monitoring is measured by the VNA 22 through transmission and reception of signals through the switch module 20, cables 48, and antennas 12 installed in the interior of the container 18. The raw data is communicated via the communications module 24 to a computing device, such as a server or servers 32, where in one embodiment, blocks 93-100 are implemented.

In one embodiment, de-embedding (93) is performed as described above in association with FIGS. 2-4B (and omitted here for brevity). Using a set of de-embedded measurements

$${S}_{xy}^{unknown} ,$$

one initial step comprises obtaining a simple background model from which scattered fields may be generated. Once a background model has been determined, calibration for system/model effects can be implemented. More particularly, and referring to block 94, the process 90 performs, in one embodiment, a parametric inversion with the de-embedded, raw measurements to obtain the known background model. Note that in some embodiments, magnitude and phase may be used to obtain the background model. That is, with the de-embedding of the disclosed embodiments, not only the magnitude (e.g., which was used in lieu of the phase in some EMI systems due to corruption of the phase component), but also the phase component of the S21 signal may be used in the process 90. The known background model consists of the grain height at the bin wall h, cone angle θ, and bulk average complex-valued permittivity ε=εr−jεi. Obtaining the known background model is achieved via a parametric inversion on the parameters p=(h, θ, ε). To determine these parameters, raw, de-embedded

$${S}_{xy}^{unknown}$$

measurements are taken and then the following cost functional is minimized according to Eqn. 1:

$$\underline{p} = \begin{matrix}{arg min}_{\sim} \\ \underline{p}\end{matrix} {\sum }_{x , y} {‖ \vert {α}_{x} ( {p}_{\_}^{\sim} ) {S}_{xy}^{unknown} \vert - \vert {H}_{xy} ( {p}_{\_}^{\sim} ) \vert ‖}_{2}^{2} , \qquad ( 1 )$$

where αₓ is a per-transmitter factor used to scale average signal levels between forward-solver-generated estimate fields H_{xy}(p) and the de-embedded, VNA measurements

$${S}_{xy}^{unknown}$$

given by Eqn. 2 below:

$${α}_{x} ( \underline{p} ) = ( {Σ}_{y} \vert {H}_{xy} ( \underline{p} ) \vert ) / ( {Σ}_{y} \vert {S}_{xy}^{unknown} \vert ) . \qquad ( 2 )$$

By using the phase and magnitude data and minimizing this objective function, parameters p are obtained, which provide a bulk estimate of the bin (container 18) contents.

Referring to block 96, the process 90 further comprises determining calibration coefficients. Given the de-embedding (93) performed previously, the calibration coefficient optimization/minimization (96) is mainly needed to account for the antennas. That is, with de-embedding performed in the process 90, the calibration coefficient minimization no longer needs to account for the effects of the cables/switch, focusing only on the antenna effects. For instance, the process calibrates the antennas based on the de-embedded

$${S}_{xy}^{unknown}$$

data. The calibration uses a set of per-channel calibration coefficients. For instance, in the case of a grain bin with twenty-four (24) antennas, twenty-four (24) calibration coefficients cx are sought. Notation is simplified by representing these coefficients as a diagonal calibration matrix C (e.g., along the diagonal, c₁, c₂, . . . c_{N}), where N is the number of antennas or antenna probes corresponding to a plurality of channels and cₓ is the (complex) calibration coefficient for channel x used to capture channel loss and phase shift. The diagonal calibration matrix C is calculated according to Eqn. 3 below:

$$C = \begin{matrix}arg min \\ \tilde{C}\end{matrix} {‖ \tilde{C} {S}^{unknown} \tilde{C} - H ( \underline{p} ) ‖}_{2}^{2} , \qquad ( 3 )$$

where S^{unknown} is the entire matrix of de-embedded

$${S}_{xy}^{unknown} ( H ( \underline{p} )$$

is defined analogously). The quantity

$${( \tilde{C} {S}^{unknown} \tilde{C} )}_{xy} = {c}_{x} {S}_{xy}^{unknown} {c}_{y}$$

and the coefficients cₓ and c_{y} serve to account for antenna effects along the channels x and y in the measurement path that are not accounted for in the forward model used to generate H (p). Based on the de-embedding (93) and calibration coefficient optimization (96), this per-channel calibration model is justified, since a significant portion of signal modification due to the measurement system is due to a magnitude and phase shift through each transmit/receive channel. Further, this channel phase shift and loss are the same whether the channel is in a transmit mode or receive mode. In one embodiment, coefficients are obtained using L2 norm minimization with raw measurements and the result from the parametric inversion 94. In general, the inputs to the example minimization formula of Eqn. 3 comprise the result of a bulk solve (e.g., which outputs grain height, cone angle, moisture content) and the measured, de-embedded data itself (e.g., complex field data or complex S-parameters). In some embodiments, other minimization techniques known to those having ordinary skill in the art may be used. Note that in some embodiments, cross-channel signal leakage (that occurs primarily inside the switch module 20) may be ignored, since a switch may be used that is specifically designed (e.g., use of ground pins, reducing the signal to ground ratio, etc.) to minimize cross-channel signals. The calibration matrix effectively assumes that each transmit/receive channel can be viewed as a lossy transmission line (not a full two-port device between the VNA and the antenna). The diagonal C-matrix also takes into account the antenna factor (that compensates for the change between the field and voltage ratio measurements).

Referring to logical block 98, the process 90 determines the calibrated scattered measurements. That is, once the per-channel calibration coefficients have been calculated, the calibrated scattered field measurements

$${H}_{xy}^{sct , ca l}$$

are computed according to Eqn. 4 below:

$${H}^{sct , c al} = {CS}^{unknown} - H ( \underline{p} ) . \qquad ( 4 )$$

The calibrated scattered fields are summarized as the channel compensated difference between a single set of de-embedded measurements S^{unknown} and a simple parametric model corresponding to those same measurements. Once calibration has been applied to produce H^{sct,cal}, an inversion algorithm (block 100) can be applied to detect hotspots (e.g., areas of high moisture content) in the material of the container 18 (e.g., the stored grain). In one embodiment, a parallel 3D Finite-Element Contrast Source Inversion Method (FEM-CSI) may be used. Further information on CSI may be found in published literature, including “Full vectorial parallel finite-element contrast source inversion method” by A. Zakaria, I. Jeffrey, and J. Lovetri, published in 2013 in Prog. Electromagn. Res., vol. 142, pp. 463-384.

Having described an embodiment of an EMI process 90, attention is directed to FIG. 5B, which illustrates an example computing device 110 that in one embodiment implements the blocks 92-100 of the EMI process 90 in software stored on a non-transitory computer readable medium. In one embodiment, the computing device 110 may be the server 32, though in some embodiments, the computing device 110 may be one of the electronic devices 26 or an edge computing device. Though described below as a single computing device (e.g., server 32) implementing the blocks 92-100 of the EMI process 90, in some embodiments, such functionality may be distributed among a plurality of devices (e.g., using plural, distributed processors) that are co-located or geographically dispersed. In some embodiments, functionality of the computing device 110 may be implemented in another device, including a programmable logic controller, application-specific integrated circuit (ASIC), field-programmable gate array (FPGA), among other processing devices. It should be appreciated that certain well-known components of computers are omitted here to avoid obfuscating relevant features of computing device 110. In one embodiment, the computing device 110 comprises one or more processors, such as processor 112, input/output (I/O) interface(s) 114, a user interface 116, and a non-transitory, computer readable medium comprising a memory 118, all coupled to one or more data busses, such as data bus 120. The memory 118 may include any one or a combination of volatile memory elements (e.g., random-access memory RAM, such as DRAM, and SRAM, etc.) and nonvolatile memory elements (e.g., ROM, hard drive, tape, CDROM, etc.). The memory 118 may store a native operating system, one or more native applications, emulation systems, or emulated applications for any of a variety of operating systems and/or emulated hardware platforms, emulated operating systems, etc. In the embodiment depicted in FIG. 5B, the memory 118 comprises an operating system 122 and application software 124.

In one embodiment, the application software 124 comprises the functionality of logical blocks 93-100 (FIG. 5A), including de-embedding module 93-1, parametric inversion module 94-1, calibration coefficient minimization/optimization module 96-1, calibrated scattered field module 98-1, and full inversion/visualization module 100-1. Functionality for modules 93-1-100-1 are described above in association with FIG. 5A, and hence further description of the same is omitted here for brevity except where noted below. Memory 118 further comprises a communications module that formats data according to the appropriate format to enable transmission or receipt of communications over the networks and/or wireless or wired transmission hardware (e.g., radio hardware). In general, the application software 124 performs the functionality described in association with the logical blocks 93-100 of FIG. 5A.

The full inversion/visualization module 100-1 may comprise known pixel-based inversion (PBI) software. For instance, the full inversion/visualization module 100-1 comprises known algorithms for performing pixel-based inversion based on the outputs provided by the calibrated scattered field module 98-1, and includes contrast source inversion (CSI) or other known visualization software. For instance, FEM-CSI may be implemented, as schematically illustrated in FIG. 5B. Digressing briefly, in general, the illuminated scattered field is measured at multiple receiver locations around an object of interest on a measurement surface, the object of interest represented using complex-valued relative permittivity εᵣ(r) as a function of position, which is converted to the so-called contrast function, reproduced below as Eqn. 5:

$$X ( r ) {=}^{Δ} \frac{ε r - ε r b}{ε r b} , \qquad ( 5 )$$

which for an air background, εrb=1 simply becomes εr−1. A final goal in the full inversion process is to reconstruct the relative permittivity εr of an object of interest from measured data on measurement surface S, where generally, iterative methods are used to iterate between solving for the contrast using an assumed total-field and solving for the total field in a domain equation using an assumed contrast. In CSI, as is known, the measured scattered field data and a functional over the imaging domain are combined within an objective function that is minimized with respect to both unknowns. For instance, when the CSI cost functional is used, the CSI cost functional is formulated using the contrast sources, which vary with transmitter and the contrast, and which is constructed as the sum of normalized data-error and domain-error functionals. For each transmitter, one component of the cost function is the norm of the difference of the measured scattered field data and the calculated scattered field at the receiver locations. Assuming a finite-element forward model, computation of one functional component of the CSI cost functional involves a matrix (the inverse of an FEM matrix operator that transforms contrast source variables (w(r)=X(r)Eₜₒₜₐₗ(r)) of an imaging domain to scattered field values within a whole domain (problem domain)) and a matrix operator (transforms field values from the whole domain to receiver locations on the measurement surface S). The other functional component (sometimes referred to as a Maxwellian regularizer, formulated using the forward model) of the CSI cost functional is a functional over the imaging domain and is calculated using an FEM model of an incident field within the imaging domain as well as the contrast, X, and contrast sources w(r), where a matrix operator transforms field values from the problem domain to points inside the imaging domain. The CSI objective functional, F^{CSI}(X, w(r)) is minimized by updating the contrast sources and the contrast variables sequentially in an iterative fashion using a conjugate gradient technique. This process is generally and schematically illustrated in FIG. 5B, though known to those having ordinary skill in the art as detailed further in the referenced publication cited above. That is, as CSI is well understood in the industry, further description of the same is omitted here for brevity. Visualization may include parameter values describing permittivity (and/or other content parameters, such as moisture content) and geometric information about the contents, including the height of the grain along the container wall, the angle of grain repose, and the average complex permittivity of the grain. In some embodiments, the rendering of the color of the grain may be indicative of average grain moisture content, among other parameters.

In some embodiments, one or more functionality of the application software 124 may be implemented in hardware. In some embodiments, one or more of the functionality of the application software 124 may be performed in more than one device. It should be appreciated by one having ordinary skill in the art that in some embodiments, additional or fewer software modules (e.g., combined functionality) may be employed in the memory 118 or additional memory. In some embodiments, a separate storage device may be coupled to the data bus 120, such as a persistent memory (e.g., optical, magnetic, and/or semiconductor memory and associated drives).

The processor 112 may be embodied as a custom-made or commercially available processor, a central processing unit (CPU), graphic processing unit (GPU), or an auxiliary processor among several processors, a semiconductor based microprocessor (in the form of a microchip), a macroprocessor, one or more ASICs, a plurality of suitably configured digital logic gates, and/or other well-known electrical configurations comprising discrete elements both individually and in various combinations to coordinate the overall operation of the computing device 110.

The I/O interfaces 114 provide one or more interfaces to the networks 28 and/or 30. In other words, the I/O interfaces 114 may comprise any number of interfaces for the input and output of signals (e.g., analog or digital data) for conveyance over one or more communication mediums.

The user interface (UI) 116 may be a keyboard, mouse, microphone, touch-type display device, head-set, and/or other devices that enable visualization of the contents and/or container as described above. In some embodiments, the output may include other or additional forms, including audible or on the visual side, rendering via virtual reality or augmented reality based techniques.

Note that in some embodiments, the manner of connections among two or more components may be varied. Further, the computing device 110 may have additional software and/or hardware, or fewer software.

The application software 124 comprises executable code/instructions that, when executed by the processor 112, causes the processor 112 to implement the functionality shown and described in association with the processes/methods described in association with FIGS. 3 and 4A-5B (and FIG. 6), and full inversion/visualization (in part via the user interface 116). As the functionality of the application software 124 has been described in the description corresponding to the aforementioned figures, further description here is omitted to avoid redundancy. In some embodiments, the application software 124 may be used to activate a moisture-affecting device (e.g., moisture-affecting device 34) based on the results of computations.

Execution of the application software 124 is implemented by the processor 112 under the management and/or control of the operating system 122. In some embodiments, the operating system 112 may be omitted. In some embodiments, functionality of application software 124 may be distributed among a plurality of computing devices (and hence, a plurality of processors).

When certain embodiments of the computing device 110 are implemented at least in part with software (including firmware), as depicted in FIG. 5B, it should be noted that the software can be stored on a variety of non-transitory computer-readable medium (including memory 118) for use by, or in connection with, a variety of computer-related systems or methods. In the context of this document, a computer-readable medium may comprise an electronic, magnetic, optical, or other physical device or apparatus that may contain or store a computer program (e.g., executable code or instructions) for use by or in connection with a computer-related system or method. The software may be embedded in a variety of computer-readable mediums for use by, or in connection with, an instruction execution system, apparatus, or device, such as a computer-based system, processor-containing system, or other system that can fetch the instructions from the instruction execution system, apparatus, or device and execute the instructions.

When certain embodiments of the computing device 110 are implemented at least in part with hardware, such functionality may be implemented with any or a combination of the following technologies, which are all well-known in the art: a discrete logic circuit(s) having logic gates for implementing logic functions upon data signals, an ASIC having appropriate combinational logic gates, a programmable gate array(s) (PGA), a field programmable gate array (FPGA), etc.

Having described certain embodiments of a de-embedding system and method for use in an EMI process, it should be appreciated within the context of the present disclosure that one embodiment of a method for de-embedding a measurement system and imaging materials in a container is shown in the flow diagram of FIG. 6, which in one embodiment may be performed by one or more components of the environment (FIG. 1). The measurement system comprises a vector network analyzer (VNA), a switch module, a plurality of cables, the container, and a plurality of antennas coupled to interior walls of the container, the switch module configured to switch signals transmitted to and received from the plurality of antennas via a plurality of channels, the VNA configured to measure scattering parameters (S-parameters) of all of the plurality of channels. The method is denoted as method 126, and is implemented in one embodiment using one or more processors of a computing device or a plurality of computing devices such as computing device 110. The method 126 comprises de-embedding a combined effect of the measurement system based on a 2-port network de-embedding technique using only a subset of the S-parameters, wherein the de-embedding is based on modelling the measurement system (128); and providing an image of the material using an inversion algorithm based on input of a calibrated S-parameter after the de-embedding (130).

Any process descriptions or blocks in flow diagrams should be understood as representing logic and/or steps in a process, and alternate implementations are included within the scope of the embodiments in which functions may be executed out of order from that shown or discussed, including substantially concurrently, or with additional steps (or fewer steps), depending on the functionality involved, as would be understood by those reasonably skilled in the art of the present disclosure.

It should be emphasized that the above-described embodiments of the present disclosure are merely possible examples of implementations, merely set forth for a clear understanding of the principles of the disclosure. As noted above, two or more of the embodiments described herein may be combined according to any combination. Many variations and modifications may be made to the above-described embodiment(s) of the disclosure without departing substantially from the scope of the disclosure. All such modifications and variations are intended to be included herein within the scope of this disclosure and protected by the following claims.

What is claimed:

1. A system, comprising:
a container configured to store a commodity;
a measurement system comprising a vector network analyzer (VNA), a switch module, a plurality of cables, and a plurality of antennas coupled to an interior wall of the container, the switch module configured to switch signals transmitted to and received from the plurality of antennas via a plurality of channels, the VNA configured to measure scattering parameters (S-parameters) of all of the plurality of channels;
at least processor; and
at least one non-transitory computer-readable storage medium storing instructions thereon that, when executed by the at least one processor, cause the measurement system to:
de-embed a combined effect of the measurement system based on a 2-port network de-embedding technique using only a subset of the S-parameters; and
provide an image of the commodity using an inversion algorithm based on input of a calibrated S-parameter after the de-embedding.

2. The system of claim 1, further comprising instructions that, when executed by the at least one processor, cause the measurement system to de-embed based on a model of the measurement system.

3. The system of claim 2, wherein the model of the measurement system comprises a series of cascaded 2-port sub-networks for each antenna pair, including a transmission switch channel, a first cable, a device under test (DUT) comprising the container with the plurality of antennas, a second cable, and a receiving switch channel.

4. The system of claim 3, further comprising instructions that, when executed by the at least one processor, cause the measurement system to measure and store all 2-port S-parameters for all channels, for a range of temperatures, through the switch module when the switch module is not connected to the plurality of cables.

5. The system of claim 4,
wherein the switch module comprises a plurality of amplifiers;
wherein the subset of the S-parameters comprises S11 and S21 data; and
wherein the system further comprises instructions that, when executed by the at least one processor, cause the measurement system:
measure the S11 data over a defined frequency band for each antenna with a transmission amplifier among the plurality of amplifiers disengaged;
determine an impulse response computed based on the S11 data measurements;
determine lengths of the cable based on the impulse response; and
model network parameters of the measurement system based further on specifications of the cable and lossy transmission equations.

6. The system of claim 5, further comprising instructions that, when executed by the at least one processor, cause the measurement system to measure S11 and S21 data for every antenna pair with the transmission amplifier engaged.

7. The system of claim 6, further comprising instructions that, when executed by the at least one processor, cause the measurement system to:
estimate an S22 measurement for the measurement system by:
removing the transmission switch channel from the S11 data measurements and approximating S11 data based on the first cable, the DUT, and the second cable; and
removing the transmission switch channel from the S22 data measurements and approximating S22 data based on the first cable, the DUT, and the second cable.

8. The system of claim 7, further comprising instructions that, when executed by the at least one processor, cause the measurement system to: determine S12 of the measurement system based on all of the 2-port S-parameters of the channels through the switching module, the cables, and the S11, S21, and S22 measurements.

9. The system of claim 8 further comprising instructions that, when executed by the at least one processor, cause the measurement system to: convert the S-parameters to transmission parameters and perform a standard calibration.

10. The system of claim 9, further comprising instructions that, when executed by the at least one processor, cause the measurement system to: convert bin measurements to S-parameters to obtain calibrated S21 data for use in the inversion algorithm.

11. The system of claim 1, wherein the 2-port network de-embedding technique uses ABCD matrices.

12. A method for de-embedding a measurement system and imaging commodity in a container, the measurement system comprising a vector network analyzer (VNA), a switch module, a plurality of cables, the container, and a plurality of antennas coupled to interior walls of the container, the switch module configured to switch signals transmitted to and received from the plurality of antennas via a plurality of channels, the VNA configured to measure scattering parameters (S-parameters) of all of the plurality of channels, the method comprising:
de-embedding a combined effect of the measurement system based on a 2-port network de-embedding technique using only a subset of the S-parameters, wherein the de-embedding is based on modelling the measurement system; and
providing an image of the commodity using an inversion algorithm based on input of a calibrated S-parameter after the de-embedding.

13. The method of claim 12, wherein the modelling is based at least partially on a series of cascaded 2-port sub-networks for each antenna pair, including a transmission switch channel, a first cable, a device under test (DUT) consisting of the container with the plurality of antennas, a second cable, and a receiving switch channel.

14. The method of claim 13, wherein the modelling comprises measuring and storing all 2-port S-parameters for all channels, for a range of temperatures, through the switch module when the switch module is not connected to the plurality of cables.

15. The method of claim 14,
wherein the switch module comprises a plurality of amplifiers;
wherein the subset of the S-parameters consists of S11 and S21 data; and
wherein the modelling further comprises:
measuring the S11 data over a defined frequency band for each antenna with a transmission amplifier among the plurality of amplifiers disengaged;
determining an impulse response computed based on the S11 data measurements;
determining lengths of the cable based on the impulse response; and
modeling network parameters of the measurement system based further on specifications of the cable and lossy transmission equations.

16. The method of claim 15, wherein the modelling further comprises measuring S11and S21 data for every antenna pair with the transmission amplifier engaged.

17. The method of claim 16, wherein the modelling further comprises estimating an S22 measurement for the measurement system by:
removing the transmission switch channel from the S11 data measurements and approximating S11 data based on the first cable, the DUT, and the second cable; and
removing the transmission switch channel from the S22 data measurements and approximating S22 data based on the first cable, the DUT, and the second cable.

18. The method of claim 17, wherein the modelling further comprises determining S12 of the measurement system based on all of the 2-port S-parameters of the channels through the switching module, the cables, and the S11, S21, and S22 measurements.

19. The method of claim 18, further comprising converting the S-parameters to transmission parameters and performing a standard calibration.

20. The method of claim 19, further comprising converting bin measurements to S-parameters to obtain calibrated S21 data for use in the inversion algorithm.
